(19) United States
(12) Patent Application Publication
(10) Pub. No.: US 2015/0129131 A1
(43) Pub. Date: May 14, 2015

(54) SEMICONDUCTOR PROCESSING APPARATUS AND PRE-CLEAN SYSTEM

(71) Applicant: TAIWAN SEMICONDUCTOR MANUFACTURING CO., LTD., Hsinchu (TW)

(72) Inventors: Chia-Ching LI, Taichung City (TW); Wei-Hao WU, Taichung City (TW); Li-Hsiang CHAO, New Taipei City (TW); Bo-Wei WANG, Taichung City (TW); Yen-Yu CHEN, Taichung City (TW); Wei ZHANG, Chupei City (TW)

(73) Assignee: TAIWAN SEMICONDUCTOR MANUFACTURING CO., LTD., Hsinchu (TW)

(21) Appl. No.: 14/080,616

(22) Filed: Nov. 14, 2013

(51) Int. Cl. H01L 21/67; H01J 37/32; H01J 37/02

(52) U.S. Cl. CPC H01L 21/67017; H01J 37/026; H01J 37/32082; H01J 37/32798; H01J 37/32449; H01J 2237/335
USPC 156/345.34; 315/85; 156/345.35

(57) ABSTRACT

A semiconductor processing apparatus includes an electromagnetic generator, an analog signal module, and an electromagnetic shield. The electromagnetic generator is capable of generating an electromagnetic field. The analog signal module is located adjacent to the electromagnetic generator and capable of generating an analog signal. The electromagnetic shield is capable of shielding the analog signal module. The electromagnetic shield includes a plurality of covering plates. Each of the covering plates and the analog signal module are apart from at least a predetermined distance.

### FIELD

The present disclosure relates to a semiconductor processing apparatus and a pre-clean system.

### BACKGROUND

Various semiconductor manufacturing processes are employed to form the semiconductor devices, including etching, lithography, ion implantation, thin film deposition, and thermal annealing. During the manufacturing of semiconductor devices, unwanted layers (or particles) are often deposited on wafers from known or unknown sources. Such deposition may occur on various layers of a wafer, such as the substrate, photoresist layer, photo mask layer, and/or other layers of the wafer.

A conventional apparatus named Aktiv.™. Preclean (“APC”) chamber is a significant feature of the Endura CuBS (copper barrier/seed) system available from Applied Materials, Inc., and provides a benign and efficient cleaning process for removal of polymeric residues and reaction of copper oxide (“CuO”) for copper low-k interconnect process schemes for 28 nm generation and below nodes. In particular, APC is designed to effectively remove polymeric residues and reduce CuO deposits while preserving the integrity of porous low and ultra-low k inter-level dielectric (“ILD”) films.

### BRIEF DESCRIPTION OF THE DRAWINGS

The disclosure can be more fully understood by reading the following detailed description of various embodiments, with reference to the accompanying drawings as follows:

FIG. 1 is a schematic diagram of a semiconductor processing apparatus in accordance with some embodiments of the present disclosure;

FIG. 2 is a perspective diagram of the analog signal module and the electromagnetic shield in FIG. 1 in accordance with some embodiments of the present disclosure;

FIG. 3 is a schematic diagram of a pre-clean system in accordance with some embodiments of the present disclosure;

FIG. 4 is a perspective diagram of the mass flow controller and the electromagnetic shield in FIG. 3 in accordance with some embodiments of the present disclosure; and

FIG. 5 is a H₂O flow fault map showing trend charts of H₂O flow controlled by a mass flow controller in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

It will be understood that, although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

Reference throughout the specification to “one embodiment” or “an embodiment” means that a particular feature, structure, implementation, or characteristic described in connection with the embodiment is included in at least one embodiment of the present disclosure. Thus, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

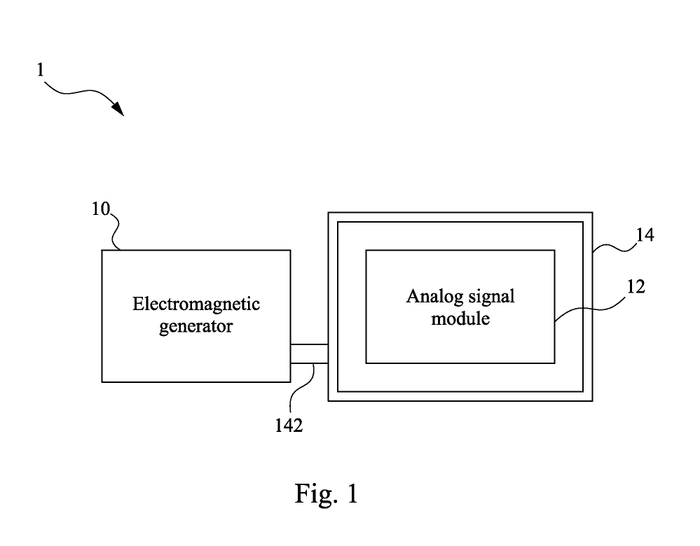

FIG. 1 is a schematic diagram of a semiconductor processing apparatus 1 in accordance with some embodiments of the present disclosure.

As shown in FIG. 1, the semiconductor processing apparatus 1 includes an electromagnetic generator 10, an analog signal module 12, and an electromagnetic shield 14. The electromagnetic generator 10 of the semiconductor processing apparatus 1 generates an electromagnetic field during operation. The analog signal module 12 of the semiconductor processing apparatus 1 is located adjacent to the electromagnetic generator 10, and is capable of generating an analog signal. The electromagnetic shield 14 of the semiconductor processing apparatus 1 is used to shield the analog signal module 12.

In some embodiments, the electromagnetic generator 10 of the semiconductor processing apparatus 1 is a remote plasma power supply, a radio-frequency power supply, or an electric magnet, but the disclosure is not limited in this regard.

In some embodiments, the analog signal module 12 of the semiconductor processing apparatus 1 is a gauge, a controller, or a driver, but the disclosure is not limited in this regard.

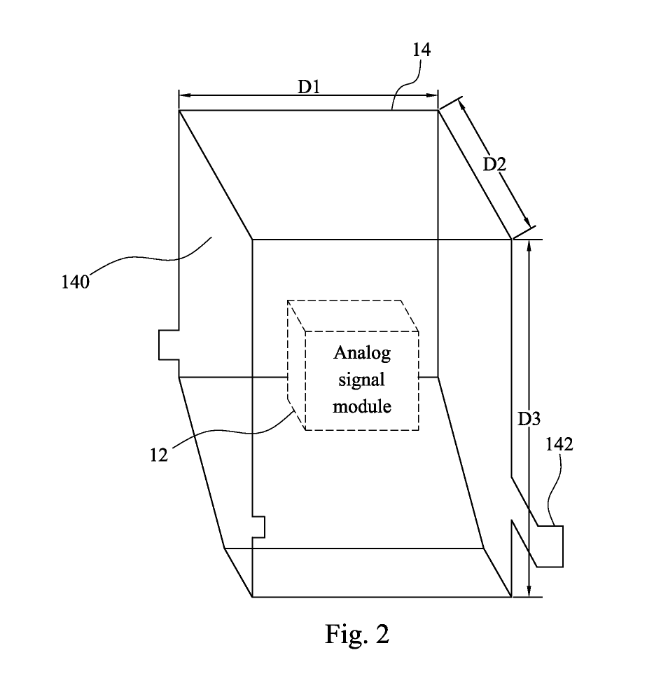

FIG. 2 is a perspective diagram of the analog signal module and the electromagnetic shield in FIG. 1 in accordance with some embodiments of the present disclosure.

As shown in FIG. 2, the electromagnetic shield 14 of the semiconductor processing apparatus 1 includes a plurality of covering plates 140. Each of the covering plates 140 of the electromagnetic shield 14 and the analog signal module 12 (indicated by dotted lines in FIG. 2) are apart from at least a predetermined distance. In some embodiments, the covering plates 140 of the electromagnetic shield 14 entirely seal the analog signal module 12, but the disclosure is not limited in this regard. Accordingly, the semiconductor processing apparatus 1 is capable of preventing the analog signal generated by the analog signal module 12 from noises caused by the electromagnetic generator 10 by using the electromagnetic shield 14.

The electromagnetic shield 14 is the practice of reducing the electromagnetic field in a space by blocking the field with barriers (i.e., the covering plates 140) made of conductive or magnetic materials. Electromagnetic shielding that blocks radio frequency electromagnetic radiation is also known as RF shielding.

The electromagnetic shield 14 can reduce the coupling of radio waves, electromagnetic fields, and the full spectrum of electromagnetic radiation. The amount of reduction depends very much upon the material used, its thickness, the size of the shielded volume and the frequency of the fields of interest and the size, shape and orientation of apertures in a shield to an incident electromagnetic field.

A variety of materials can be used as electromagnetic shielding to protect the analog signal module 12. Examples include ionized gas in the form of plasma, metal foam with gas-filled pores, or simply sheet metal. In order for holes within the electromagnetic shield 14 to be present, they must be considerably smaller than any wavelength from the electromagnetic field. If the electromagnetic shield 14 contains any openings larger than the wavelength, it cannot effectively prevent the analog signal module 12 from becoming compromised.

Particularly, RF shielding enclosures filter a range of frequencies for specific conditions. Copper is used for RF shielding because it absorbs radio and magnetic waves. Properly designed and constructed copper RF shielding enclosures satisfy most RF shielding needs.

In some embodiments, the predetermined distance is equal to or larger than 20 mm, but the disclosure is not limited in this regard.

In some embodiments, the thickness of each of the covering plates 140 is equal to or larger than 1 mm, but the disclosure is not limited in this regard.

The number of the covering plates 140 in FIG. 2 is given for illustrative purposes. Other numbers and configurations of covering plates 140 are within the contemplated scope of the present disclosure.

As shown in FIG. 1 and FIG. 2, the electromagnetic shield 14 of the semiconductor processing apparatus 1 further includes a fixing bracket 142. The fixing bracket 142 of the electromagnetic shield 14 is connected to one of the covering plates 140 and is fixed to a housing of the electromagnetic generator 10.

As shown in FIG. 2, in some embodiments, the length D1 of the electromagnetic shield 14 is 320 mm, the width D2 of the electromagnetic shield 14 is 180 mm, and the height D3 of the electromagnetic shield 14 is 430 mm, but the disclosure is not limited in this regard.

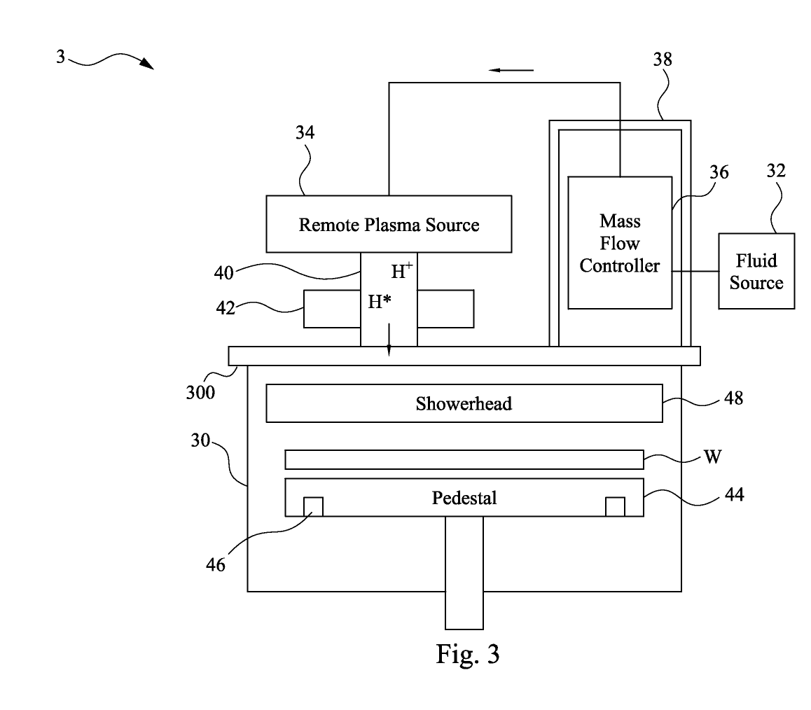

FIG. 3 is a schematic diagram of a pre-clean system 3 in accordance with some embodiments of the present disclosure.

As shown in FIG. 3, a pre-clean system 3 includes a cleaning chamber 30, a fluid source 32, a remote plasma source 34, a mass flow controller 36, and an electromagnetic shield 38. The cleaning chamber 30 of the pre-clean system 3 includes an aluminum lid 300 (i.e., the material of the lid 300 includes aluminum). The fluid source 32 of the pre-clean system 3 is capable of providing a plurality fluids. For example, the fluid source 32 of the pre-clean system 3 is capable of providing Helium, H₂O, Argon, and Hydrogen, but the disclosure is not limited in this regard. The remote plasma source 34 of the pre-clean system 3 is disposed on the aluminum lid 300 of the cleaning chamber 30, and is capable of generating a plasma. The mass flow controller 36 of the pre-clean system 3 is connected to the fluid source 32 and communicated to the remote plasma source 34, so as to selectively allow at least one of the fluids to flow toward the remote plasma source 34. The electromagnetic shield 38 of the pre-clean system 3 is disposed on the aluminum lid 300 of the cleaning chamber 30, and is used to shield the mass flow controller 36.

The mass flow controller 36 is a device used to measure and control the flow of fluids and gases. The mass flow controller 36 is designed and calibrated to control a specific type of fluid or gas at a particular range of flow rates. The mass flow controller 36 can be given a setpoint from 0 to 100% of its full-scale range but is typically operated in the 10 to 90% of full scale where the best accuracy is achieved. The mass flow controller 36 will then control the rate of flow to the given setpoint.

The mass flow controller 36 has an inlet port, an outlet port, a mass flow sensor, and a proportional control valve (not shown). The mass flow controller 36 is fitted with a closed loop control system which is given an input signal by the operator (or an external circuit/computer) that it compares to the value from the mass flow sensor and adjusts the proportional valve accordingly to achieve the required flow. The flow rate is specified as a percentage of its calibrated full-scale flow and is supplied to the mass flow controller 36 as a voltage signal.

The mass flow controller 36 requires the supply gas to be within a specific pressure range. Low pressure will starve the mass flow controller 36 of gas and it may fail to achieve its setpoint. High pressure may cause erratic flow rates.

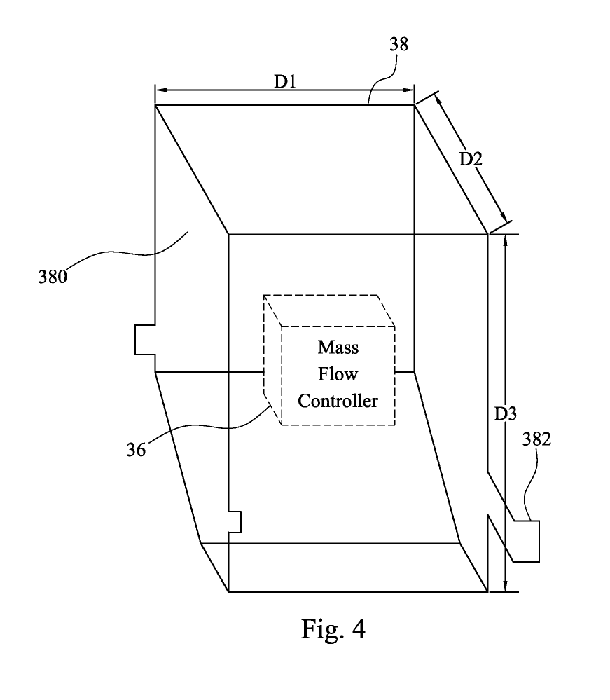

FIG. 4 is a perspective diagram of the mass flow controller 36 and the electromagnetic shield 38 in FIG. 3 in accordance with some embodiments of the present disclosure.

As shown in FIG. 4, the electromagnetic shield 38 of the pre-clean system 3 includes a plurality of covering plates 380. The covering plates 380 of the electromagnetic shield 38 and the mass flow controller 36 (indicated by dotted lines in FIG. 2) are apart from a plurality of distances respectively. One of the distances is longer than any of the other distances to thereby form a shortest distance. Accordingly, the pre-clean system 3 is capable of preventing the mass flow controller 36 from electromagnetic interference caused by the remote plasma source 34 by using the electromagnetic shield 38, so that the mass flow controller 36 can precisely control the processing fluid (e.g., H₂O) to flow into the cleaning chamber 30.

In some embodiments, the shortest distance is equal to or larger than 20 mm, but the disclosure is not limited in this regard.

The number of the covering plates 380 in FIG. 4 is given for illustrative purposes. Other numbers and configurations of covering plates 380 are within the contemplated scope of the present disclosure.

In some embodiments, the electromagnetic shield 38 of the pre-clean system 3 further includes a fixing bracket 382. The fixing bracket 382 of the electromagnetic shield 38 is connected to at least one of the covering plates 380 and fixed to a housing of the remote plasma source 34.

As shown in FIG. 4, in some embodiments, the length D1 of the electromagnetic shield 14 is 320 mm, the width D2 of the electromagnetic shield 14 is 180 mm, and the height D3 of the electromagnetic shield 14 is 430 mm, but the disclosure is not limited in this regard.

In some embodiments, the plasma generated by the remote plasma source 34 of the pre-clean system 3 is Hydrogen ion/radical plasma. The pre-clean system 3 further includes an applicator tube 40 and an ion filter 42. The applicator tube 40 of the pre-clean system 3 is communicated between the remote plasma source 34 and the cleaning chamber 30. The ion filter 42 of the pre-clean system 3 is disposed on the applicator tube 40 and located between the remote plasma source 34 and the cleaning chamber 30, and is used to filter ions in the applicator tube 40.

The remote plasma source 34 is defined by the fact that the plasma is only generated and existing in the remote plasma source 34 itself, not in the cleaning chamber 30. No plasma, only radicals (i.e., Hydrogen radicals H*) are reaching the cleaning chamber 30. Hence, reactive hydrogen radicals H* generated by the remote plasma source 34 are capable of entering the cleaning chamber 30 via the applicator tube 40 and the aluminum lid 300.

Therefore, the remote plasma source 34 is ideal for applications that necessarily need to avoid physical effects as ion bombardment and high thermal load. The radicals generated by the remote plasma source 34 are creating only a chemical reaction at the surface of the substrates. That is leading to extremely low thermal load and damage free etching at high rates.

As shown in FIG. 3, the pre-clean system 3 further includes a pedestal 44, a heater 46, and a showerhead 48. The pedestal 44 of the pre-clean system 3 is disposed in the cleaning chamber 30, and is used to support a wafer or substrate W. The heater 46 of the pre-clean system 3 is disposed in the pedestal 44, and is used to heat the pedestal 44 to a predetermined temperature. The pedestal 44 heated by the heater 46 in the cleaning chamber 30 is capable of maximizing process efficiency with optimized process variables. The showerhead 48 of the pre-clean system 3 is disposed in the cleaning chamber 30 and over the wafer or substrate W. The Hydrogen ion/radical plasma generated by the remote plasma source 34 passes through the showerhead 48 and processes onto the wafer or substrate W. The Hydrogen radicals H* passing through the showerhead 48 can efficiently remove polymeric residues on the wafer or substrate W and reduce CuO deposited on the wafer or substrate W.

Neutral hydrogen radicals H* are unaffected by the electromagnetic field and continue to drift with the gas out of the apertures of the showerhead 48. The hydrogen radicals H* form an excited but neutral gas and do not technically constitute a plasma containing ions and electrons. This description should not be taken as limiting the ion filter to a magnetic filter and other ion filters may be used. Non-limiting examples of suitable ion filters include electrostatic lenses, quadrupole deflectors, Einzel lenses and ion traps.

In some embodiments, the fluid flowing to the remote plasma source 34 controlled by the mass flow controller 36 is a H₂O flow. The H₂O flow is capable of protecting quartz process kits damage by the Hydrogen radicals H*, and has advantage of particle improvement.

In some embodiments, the cleaning chamber 30 of the pre-clean system 3 is a PVD chamber, but the disclosure is not limited in this regard.

In other words, the pre-clean system 3 in FIG. 3 is a remote plasma cleaning system. Damage to the substrate can be significantly reduced by cleaning with reactive hydrogen radicals H* generated by the remote plasma source 34. As shown in FIG. 3, the pre-clean system 3 is designed to eliminate damaging Hydrogen ions (H⁺) from reaching the wafer or substrate W by providing the ion filter 42 between the remote plasma source 34 and the cleaning chamber 30 in which the wafer or substrate W to be cleaned is disposed on a pedestal 44 beneath a showerhead 48.

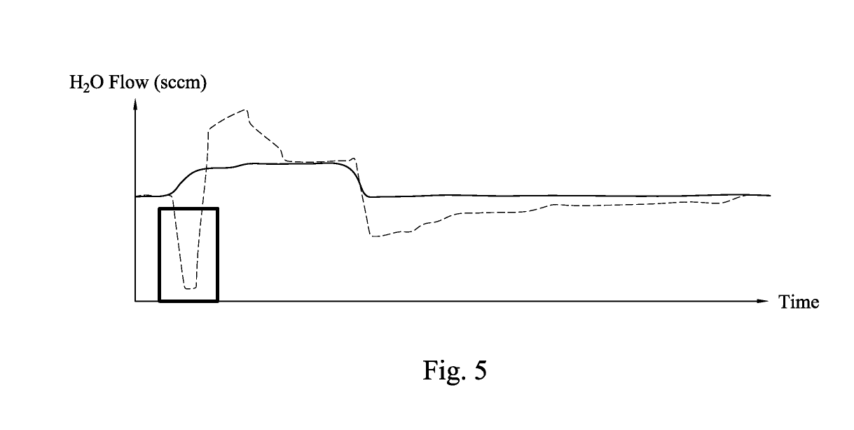

FIG. 5 is a H₂O flow fault map showing trend charts of H₂O flow controlled by a mass flow controller 36 in accordance with some embodiments of the present disclosure.

As shown in FIG. 5, the dotted line indicates an abnormal chart of a H₂O flow controlled by the mass flow controller 36 without using the electromagnetic shield 38, and the solid line indicates a normal chart of a H₂O flow controlled by the mass flow controller 36 using the electromagnetic shield 38. Without using the electromagnetic shield 3, high alarm ratio (3 times/day) causes wafer yield lost and increases EE/PE rework loading. It can be clearly seen that by using the electromagnetic shield 38 to shielding the mass flow controller 36, the H₂O flow drop of the abnormal chart that indicated by the border can be effectively improved. That is, the electromagnetic shield 38 can effectively prevent the mass flow controller 36 from the electromagnetic interference of the remote plasma source 34.

The above illustrations include exemplary steps, but the steps are not necessarily performed in the order shown. Steps may be added, replaced, changed order, and/or eliminated as appropriate, in accordance with the spirit and scope of various embodiments of the present disclosure.

In some embodiments, a semiconductor processing apparatus includes an electromagnetic generator, an analog signal module, and an electromagnetic shield. The electromagnetic generator generates an electromagnetic field. The analog signal module is located adjacent to the electromagnetic generator for generating an analog signal. The electromagnetic shield is used to shield the analog signal module. The electromagnetic shield includes a plurality of covering plates. Each of the covering plates and the analog signal module are apart from a predetermined distance.

Also disclosed is a pre-clean system includes a cleaning chamber, a remote plasma source, a mass flow controller, and an electromagnetic shield. The cleaning chamber includes a lid. The remote plasma source is disposed on the lid for generating a plasma. The mass flow controller is communicated to the remote plasma source for controlling a fluid to flow toward the remote plasma source. The electromagnetic shield is disposed on the lid for shielding the mass flow controller.

A pre-clean system is also disclosed to include a cleaning chamber, a fluid source, a remote plasma source, a mass flow controller, and an electromagnetic shield. The cleaning chamber includes an aluminum lid. The fluid source is used to provide a plurality fluids. The remote plasma source is disposed on the aluminum lid for generating a plasma. The mass flow controller is connected to the fluid source and communicated to the remote plasma source for selectively allowing at least one of the fluids to flow toward the remote plasma source. The electromagnetic shield is disposed on the aluminum lid for shielding the mass flow controller.

According to the foregoing recitations of the embodiments of the disclosure, it can be seen that the semiconductor processing apparatus is capable of preventing the analog signal generated by the analog signal module (e.g., a gauge, a controller, a driver, and etc.) from noise caused by electromagnetic generator 10 by using the electromagnetic shield. Similarly, the pre-clean system is capable of preventing the mass flow controller from electromagnetic interference caused by the remote plasma source by using the electromagnetic shield, so that the mass flow controller can precisely control the processing fluid to flow into the cleaning chamber. Therefore, the high alarm ratio that causes wafer yield lost and increases EE/PE rework loading can be improved. In addition, the electromagnetic shield is low cost for hardware change.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing apparatus comprising:
an electromagnetic generator configured to generate an electromagnetic field;
an analog signal module located adjacent to the electromagnetic generator and configured to generate an analog signal; and
an electromagnetic shield configured to shield the analog signal module, the electromagnetic shield comprising a plurality of covering plates, wherein each of the covering plates and the analog signal module are apart from at least a predetermined distance.

2. The semiconductor processing apparatus of claim 1, wherein the predetermined distance is equal to or larger than 20 mm.

3. The semiconductor processing apparatus of claim 1, wherein the electromagnetic generator comprises a remote plasma power supply, a radio-frequency power supply, or an electric magnet.

4. The semiconductor processing apparatus of claim 1, wherein the analog signal module comprises a gauge, a controller, or a driver.

5. The semiconductor processing apparatus of claim 1, wherein the covering plates entirely seal the analog signal module.

6. The semiconductor processing apparatus of claim 1, wherein the electromagnetic shield further comprises a fixing bracket fixed to a housing of the electromagnetic generator.

7. The semiconductor processing apparatus of claim 1, wherein the thickness of each of the covering plates is equal to or larger than 1 mm.

8. A pre-clean system comprising:
a cleaning chamber comprising a lid;
a remote plasma source disposed on the lid for generating a plasma;
a mass flow controller communicated to the remote plasma source for controlling a fluid to flow toward the remote plasma source; and
an electromagnetic shield disposed on the lid for shielding the mass flow controller.

9. The pre-clean system of claim 8, wherein the electromagnetic shield comprises a plurality of covering plates, the covering plates and the mass flow controller are apart from a plurality of distances respectively, and one of the distances is longer than any of the other distances to thereby form a shortest distance.

10. The pre-clean system of claim 9, wherein the shortest distance is equal to or larger than 20 mm.

11. The pre-clean system of claim 8, wherein the plasma comprises Hydrogen ion/radical plasma.

12. The pre-clean system of claim 8, further comprising:
an applicator tube communicated between the remote plasma source and the cleaning chamber; and
an ion filter disposed on the applicator tube and located between the remote plasma source and the cleaning chamber for filtering ions in the applicator tube.

13. The pre-clean system of claim 12, further comprising:
a pedestal disposed in the cleaning chamber for supporting a wafer or substrate; and
a showerhead disposed in the cleaning chamber and over the wafer or substrate, wherein the plasma passes through the showerhead and processes onto the wafer or substrate.

14. The pre-clean system of claim 8, wherein the lid and the electromagnetic shield seal the mass flow controller.

15. The pre-clean system of claim 8, wherein the fluid comprises a H₂O flow.

16. The pre-clean system of claim 8, wherein the cleaning chamber comprises a PVD chamber.

17. The pre-clean system of claim 8, wherein the material of the lid comprises aluminum.

18. A pre-clean system comprising:
a cleaning chamber comprising an aluminum lid;
a fluid source configured to provide a plurality fluids;
a remote plasma source disposed on the aluminum lid for generating a plasma;
a mass flow controller connected to the fluid source and communicated to the remote plasma source for selectively allowing at least one of the fluids to flow toward the remote plasma source; and
an electromagnetic shield disposed on the aluminum lid for shielding the mass flow controller.

19. The pre-clean system of claim 18, wherein the electromagnetic shield comprises:
a plurality of covering plates disposed on the aluminum lid, the covering plates and the aluminum lid sealing the mass flow controller; and
a fixing bracket connected to at least one of the covering plates and fixed to a housing of the remote plasma source.

20. The pre-clean system of claim 18, wherein the plasma is Hydrogen ion/radical plasma, the pre-clean system further comprises:
an applicator tube communicated between the remote plasma source and the cleaning chamber;
an ion filter disposed on the applicator tube and located between the remote plasma source and the cleaning chamber for filtering Hydrogen ions in the applicator tube;
a pedestal disposed in the cleaning chamber for supporting a wafer or substrate;
a heater disposed in the pedestal for heating the pedestal to a predetermined temperature; and
a showerhead disposed in the cleaning chamber and over the wafer or substrate, wherein the Hydrogen ion/radical plasma passes through the showerhead and processes onto the wafer or substrate.
